(19) United States
(12) Patent Application Publication
(10) Pub. No.: US 2012/0153321 A1
(43) Pub. Date: Jun. 21, 2012

(54) ORGANIC LIGHT EMITTING DIODE DISPLAY

(75) Inventors: Jin-Koo Chung, Yongin-city (KR); Jun-Ho Choi, Yongin-city (KR); Joo-Hyeon Lee, Yongin-city (KR); Seong-Min Kim, Yongin-city (KR); Byoung-Hee Park, Yongin-city (KR)

(73) Assignee: Samsung Mobile Display Co., Ltd., Yongin-city (KR)

(21) Appl. No.: 13/100,996

(22) Filed: May 4, 2011

(30) Foreign Application Priority Data
Dec. 20, 2010 (KR) 10-2010-0130811

(51) Int. Cl. H01L 51/52

(52) U.S. Cl. 257/91; 257/E51.018

(57) ABSTRACT

An OLED display is disclosed. The display includes a substrate main body where a plurality of pixel areas are formed. Each pixel area includes an opaque area and a transparent area, and the opaque area includes a display area that emits light. The display area and the transparent area are separated by a conductive line disposed therebetween.

### CROSS-REFERENCE TO RELATED APPLICATIONS

This application claims priority to and the benefit of Korean Patent Application No. 10-2010-0130811 filed in the Korean Intellectual Property Office on Dec. 20, 2010, the entire contents of which are incorporated herein by reference.

### BACKGROUND

1. Field

The disclosed technology relates to an organic light emitting diode (OLED) display. More particularly, the described technology relates generally to a transparent OLED display.

2. Description of the Related Technology

An organic light emitting diode (OLED) display is a self-emissive display that displays an image with an organic light emitting element, which emits light.

Further, the OLED display can be made as a transparent display that enables a user to see an object or an image located on the opposite through the OLED display. For example, when the OLED display is off, an object on the opposite side can be seen, and when the OLED display is on, an image is displayed with light from the organic light emitting elements.

Thus, the transparent OLED display includes opaque areas where pixels including an organic light emitting element and a thin film transistor are formed and transparent areas through which light is transmitted. Here, the transparent areas have widths of several to several tens of micrometers such that light is transmitted and the object at the opposite side is viewed, and is regularly arranged between pixels.

Transmittance is increased as the transparent area is increased, but interference occurs due to a deposition process for forming a cathode in the opaque area so that the cathode made of an opaque material interferes with the transparent area. As described, when the cathode interferes with the transparent area, the effective transparent area is decreased so that the transmittance is deteriorated and a transmission image may be distorted.

The above information disclosed in this Background section is only for enhancement of understanding of the background of the described technology and therefore it may contain information that does not form the prior art that is already known in this country to a person of ordinary skill in the art.

### SUMMARY OF CERTAIN INVENTIVE ASPECTS

One inventive aspect is an organic light emitting diode (OLED) display. The display includes a substrate main body having a plurality of pixel areas formed thereon, where each pixel area includes an opaque area, and the opaque area includes a display area that emits light. Each pixel area also includes a transparent area. The display area and the transparent area are separated by a conductive line disposed therebetween.

Another inventive aspect is an organic light emitting diode (OLED) display including a substrate main body having a plurality of pixel areas formed thereon. Each pixel area includes an opaque area having a display area configured to emit light, and a transparent area. The display area and the transparent area are separated by a conductive line disposed between the display area and the transparent area. The display also includes a transparent display unit configured to emit light formed in the transparent area.

### BRIEF DESCRIPTION OF THE DRAWINGS

FIG. 1 is a layout view of an organic light emitting diode (OLED) display according to a first exemplary embodiment.

FIG. 2 is an enlarged layout view of a sub-pixel of FIG. 1.

FIG. 3 is a cross-sectional view of FIG. 2, taken along the line III-III.

FIG. 4 is a layout view of an OLED display according to a second exemplary embodiment.

FIG. 5 is a layout view of an OLED display according to a third exemplary embodiment.

FIG. 6 is a layout view of an OLED display according to a fourth exemplary embodiment.

### DETAILED DESCRIPTION OF CERTAIN INVENTIVE EMBODIMENTS

Certain aspects and features are described more fully hereinafter with reference to the accompanying drawings, in which exemplary embodiments are shown. As those skilled in the art would realize, the described embodiments may be modified in various ways, without departing from the spirit or scope of the present invention.

The drawings and description are to be regarded as illustrative in nature and not restrictive. Like reference numerals generally designate like elements throughout the specification. In subsequent exemplary embodiments, generally elements different from those of the first exemplary embodiment are described.

The size and thickness of each component shown in the drawings are arbitrarily shown for understanding and ease of description, but the present invention is not limited thereto. In addition, in the drawings, the thickness of layers, films, panels, regions, etc., may be exaggerated for clarity. It will be understood that when an element such as a layer, film, region, or substrate is referred to as being “on” another element, it can be directly on the other element or intervening elements may also be present.

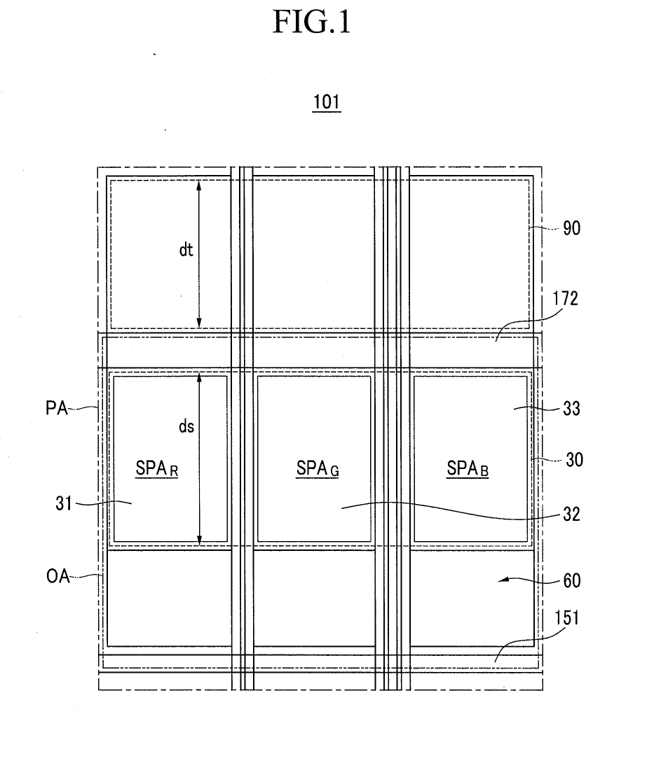

Hereinafter, an organic light emitting diode (OLED) display 101 according to a first exemplary embodiment is described with reference to FIG. 1 to FIG. 3. As shown in FIG. 1 to FIG. 3, the OLED display 101 according to the first exemplary embodiment includes a substrate body 111 with a pixel area PA including a plurality of sub-pixels SPA_{R}, SPA_{G}, and SPA_{B}, an organic light emitting diode (OLED) 70, and thin film transistors (TFTs) 10 and 20. The organic light emitting diode 70 and the thin film transistors 10 and 20 are formed in each sub-pixel. In addition, the OLED display 101 further includes conductive lines 151, 171, and 172 connected with the thin film transistors 10 and 20 or the organic light emitting diode 70.

The substrate main body 111 may be formed with a transparent insulating substrate made of glass, quartz, ceramic, and the like, or may be formed with a transparent flexible substrate made of plastic and the like. The pixel area PA is substantially formed in the shape of a square. However, the first exemplary embodiment is not limited thereto, and the pixel area PA may be formed in the shape of a rectangular.

Hereinafter, the pixel area PA, the plurality of sub-pixels SPA_{R}, SPA_{G}, and SPA_{B}, a transparent area 90, and a display area 30 are formed in the general shape of a quadrangle. However, in some embodiments, the areas may have rounded edges or corners.

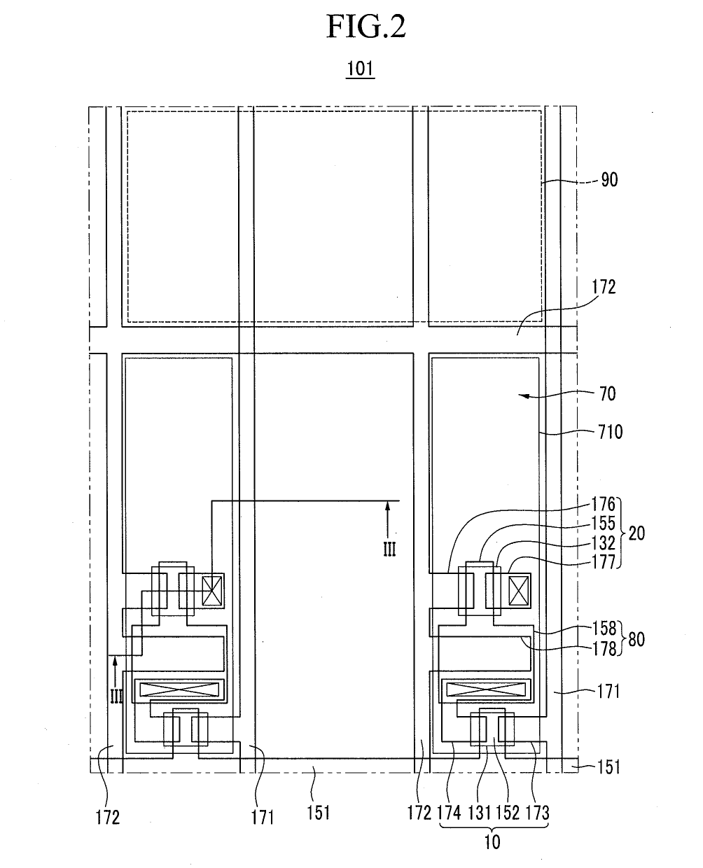

In the pixel area PA, each of the sub-pixels SPA_{R}, SPA_{G}, and SPA_{B} includes an opaque area OA and a transparent area 90. The opaque area OA includes a display area 30 and a thin film transistor area 60. As shown in FIG. 2, the organic light emitting diode 70, the thin film transistors 10 and 20, and a capacitor 80 are formed in the opaque area OA. The conductive lines include a gate line 151, a data line 171, and a common power line 172. A transparent insulating layer for light transmission is formed in the transparent area 90.

In the first exemplary embodiment, three display units of a red display unit 31, a green display unit 32, and a blue display unit 33 are formed in the display area 30. However, the first exemplary embodiment is not limited thereto. Thus, two display units or four or more displays may be included in one display area.

According to the first exemplary embodiment, an organic light emitting diode 70 formed in the red display unit 31 emits light of a red-based color, an organic light emitting diode 70 formed in the green display unit 32 emits light of a green-based color, and an organic light emitting diode 70 formed in the blue display unit 33 emits light of a blue-based color. However, the light emitted from each display unit is not limited to a particular color. For example, light of color, emitted from each display unit may be appropriately controlled according to the number of display units in the display area. All the display units 31, 32, and 33 may have the same area, each may have a different area, or they may partially have the same area.

Further, in the first exemplary embodiment, the transparent area 90 is formed in the shape of a rectangular in one pattern. In addition, the plurality of display units 31, 32, and 33 are arranged in parallel with each other along a length direction of the transparent area 90. In this case, the common power line 172 is disposed between the display area 30 and the transparent area 90. Accordingly, the display area 30 and the transparent area 90 are disposed at a distance from each other, with the common power line 172 therebetween.

When each display unit is formed in the display area 30, an opaque cathode 730 may be formed in the area of the transparent area 90 due to a process margin during a deposition process for the opaque cathode 730 such that the effective area of the transparent area 90 may be decreased. Because the common power line 172 spaces apart the transparent area 90 from the opaque cathode 730, the common power line 172 prevents the area of the transparent area 90 from be decreased. That is, the cathode 730 does not interfere with the transparent area 90 on the other side of the common power line 172 even though the formation range of the cathode 730 somewhat exceeds the area of the display area 30. Here, the cathode 730 may be made of Al, Ag, and the like.

As described, in the first exemplary embodiment, the common power line 172, that is, a conductive line is disposed between the display area 30 and the transparent area 90, that is, between the cathode 730 and the transparent area 90 of the display area 30.

### Exemplary Embodiment

For example, a deposition process error may be 15 μm. In addition, as shown in FIG. 1, the width of the transparent area 90 is dt, and the width of the display area 30 is ds. The common electrode 172 is formed between the display area 30 and the transparent area 90. As an example embodiment, the width ds of the display area 30 may be 79 μm and the width dt of the transparent area 90 may be 96.5 μm.

### Comparative Example

In the comparative example, a conductive line such as a common power line is not disposed between a display area and a transparent area such that the display area and the transparent are arranged adjacent to each other. In this case, the width ds of the display area may be 79 μm but the width dt of the transparent area should be, for example, 70 μm that is smaller than the width dt in the exemplary embodiment due to allow for margin because of the interference of the cathode disposed in the display area.

As described, the transparent area of the OLED display 101 according to the first exemplary embodiment is increased so that the light transmittance can be increased and the image distortion can be minimized.

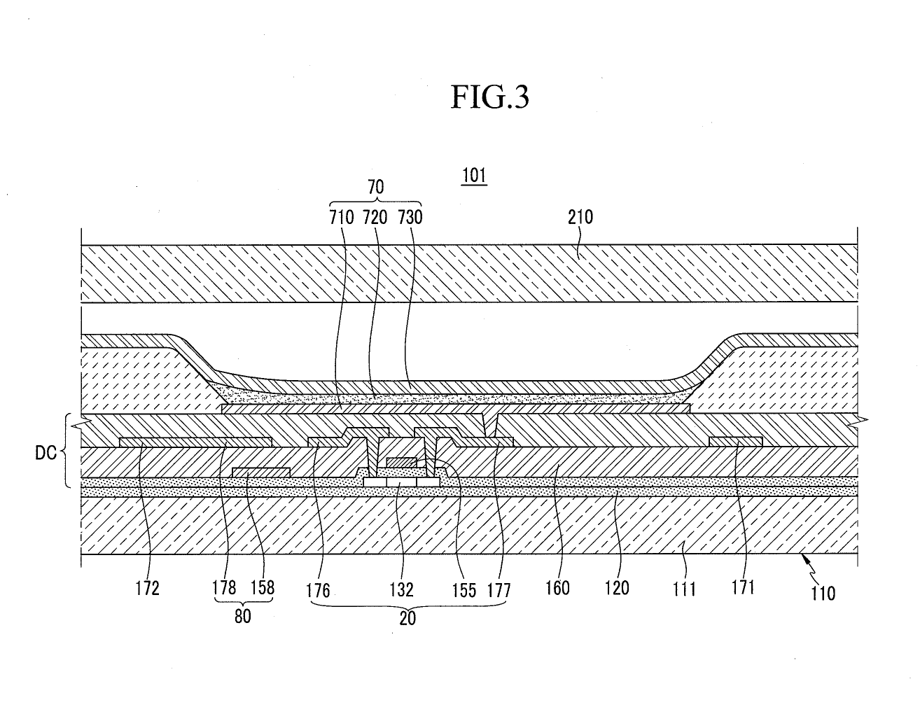

Hereinafter, an internal structure of the OLED display 101 is described with reference to FIG. 2 and FIG. 3. In FIG. 2 and FIG. 3, an active matrix (AM) organic light emitting diode display having a 2Tr-1 Cap structure which includes two thin film transistors (TFTs) 10 and 20 and one capacitor 80 in one pixel is shown, but the present invention is not limited thereto.

Thus, the OLED display 101 may include three or more thin film transistors and one or more capacitors in one pixel, and may further include a separate wire to thereby have various structures. Here, the pixel may represent a minimum unit displaying an image. The OLED display 101 displays the image with a plurality of pixels.

As shown in FIG. 2 and FIG. 3, the switching thin film transistor 10, the driving thin film transistor 20, the capacitor 80, and the organic light emitting diode 70 are formed in each pixel on the substrate main body 111. Here, a circuit including a switching thin film transistor 10, a driving thin film transistor 20, and a capacitor 80 is referred to as a driving circuit DC. In addition, a buffer layer 120 may further be formed between the substrate main body 111, the driving circuit DC, and the organic light emitting diode 70. The buffer layer 120 may be formed of a single layer made of silicon nitride (SiNx) or a dual layer structure in which silicon nitride (SiNx) and silicon oxide (SiO2) are laminated. The buffer layer 120 prevents an unnecessary element such as an impurity element or moisture from penetrating and also planarizes the surface. However, the buffer layer 120 is not necessarily required and may be omitted depending on the kind of the substrate body 111 and a process condition.

The gate lines 151 arranged along one direction, the data lines 171 crossing the gate line 151 in an insulated manner, and the common power lines 172 are further formed on the substrate main body 111. One pixel may be defined by the boundary of the gate line 151, the data line 171, and the common power line 172, but it is not limited thereto.

The organic light emitting diode 70 includes an anode 710, an organic emission layer 720 formed on the anode 710, and a cathode 730 formed on the organic emission layer 720. Holes and electrodes are injected into the organic emission layer 720 respectively from the anode 710 and the cathode 730. An exiton, in which the hole and the electron injected into the organic emission layer 720 are coupled to each other, falls down from an excited state to a ground state, light emission occurs.

The capacitor 80 includes a pair of capacitor plates 158 and 178, with interlayer insulating layer 160 therebetween. Here, the interlayer insulating layer 160 is a dielectric. The capacitance of the capacitor 80 may depend on the charges charged at the capacitor 80 and a voltage between the two capacitor plates 158 and 178.

The switching thin film transistor 10 includes a switching semiconductor layer 131, a switching gate electrode 152, a switching source electrode, 173 and a switching drain electrode 174. The driving thin film transistor 20 includes a driving semiconductor layer 132, a driving gate electrode 155, a driving source electrode 176, and a driving drain electrode 177.

The switching thin film transistor 10 is used as a switch for selecting a pixel for light emission. The switching gate electrode 152 is connected to the gate line 151. The switching source electrode 173 is connected to the data line 171. The switching drain electrode 174 is disposed at a distance from the switching source electrode 173 and connected with one 158 of the capacitor plates 158 and 178.

The driving thin film transistor 20 applies driving power to a pixel electrode 710 for light emission of an organic emission layer 720 of an organic light emitting diode 70 in the selected pixel. The driving gate electrode 155 is connected with the capacitor plate 158 connected with the switching drain electrode 174. The driving source electrode 176 and the other capacitor plate 178 are respectively connected with the common power line 172. The driving drain electrode 177 is connected with the pixel electrode 710 of the organic light emitting diode 70 through a contact hole.

With such a structure, the switching thin film transistor 10 is driven by a gate voltage applied to the gate line 151 and transmits a data voltage applied to the data line 171 to the driving thin film transistor 20. A voltage corresponding to a difference between a common voltage applied to the driving thin film transistor 20 from the common power line 172 and the data voltage transmitted from the switching thin film transistor 10 is stored in the capacitor 80, and a current corresponding to the voltage stored in the capacitor 80 flows to the organic light emitting diode 70 through the driving thin film transistor 20 such that the organic light emitting diode 70 emits light.

A transparent encapsulation member 210 is disposed on the organic light emitting diode 70. The encapsulation member 210 seals the substrate main body 111 and a sealant (not shown) to seal an inner space therebetween, and protects the organic light emitting diodes 70 and the thin film transistors 10 and 20. In the first exemplary embodiment, the encapsulation member 210 is a transparent insulating substrate such as a glass substrate or a plastic substrate. However, the first exemplary embodiment is not limited thereto. Thus, a transparent encapsulation thin film including a plurality of protection layers that are sequentially stacked may be used as the encapsulation member 210.

In addition, the structures of the thin film transistors 10 and 20 and the organic light emitting diode 70 are not limited to the embodiments of FIG. 2 and FIG. 3. That is, the structures of the thin film transistors 10 and 20 and the organic light emitting diode 70 may be variously modified.

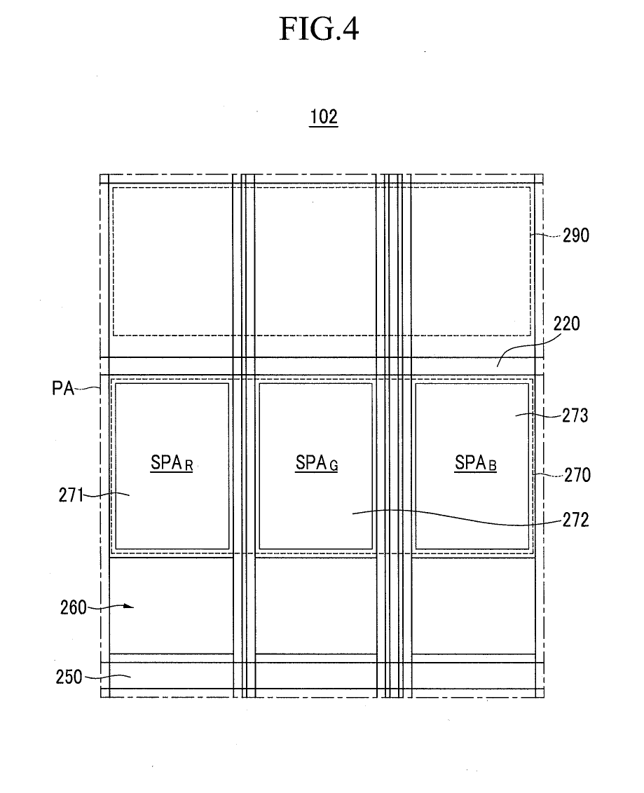

Hereinafter, an OLED display 102 according to a second exemplary embodiment is described with reference to FIG. 4. As shown in FIG. 4, the OLED display 102 includes a pixel area PA including a plurality of sub-pixels SPA_{R}, SPA_{G}, and SPA_{B}. The pixel area PA includes a display area 270 including a transparent area 290 and a plurality of display units 271, 272, and 273 and a gate line 220 disposed between the display area 270 and the transparent area 290. Further, the pixel area PA includes a thin film transistor area 260 that controls the display area 270 between the transparent area 290 and the thin film transistor area 260 and a common power line 250 disposed adjacent to the thin film transistor area 260. That is, in the second exemplary embodiment, the display area 270 and the transparent area 290 are disposed at a distance from each other, with the gate line 220 therebetween, and a cathode of an organic light emitting diode formed in the display area 290 does not extend to the transparent area 290 over than gate line 220.

When the gate line 220 is formed between the display area and the transparent area as in the second exemplary embodiment, the cathode in the display area can be prevented from being formed extending to the transparent area.

In the second exemplary embodiment, the display area 270, the thin film transistor area 260, the gate line 220, and the common power line 250 are formed in the opaque area.

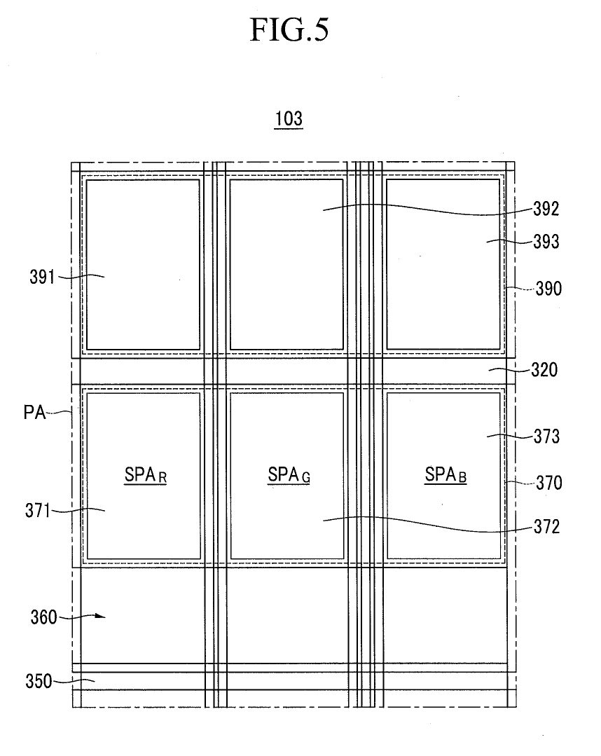

Hereinafter, an OLED display 103 according to a third exemplary embodiment is described with reference to FIG. 5.

As shown in FIG. 5, the OLED display 103 according to the third exemplary embodiment includes a pixel area PA that includes a transparent area 390 including a plurality of transparent display units 391, 392, and 393, a display area 370 including a plurality of opaque display units 371, 372, and 373, and a common power line 320 disposed between the display area 370 and the transparent area 390. That is, in the third exemplary embodiment, not only the display area 370 but also the transparent area 390 emits light.

In the third exemplary embodiment, the transparent area 390 and the display area 370 are disposed at a distance from each other, with the common power line 320 therebetween so that a cathode of an organic light emitting diode in the display area 370 cannot extend to the transparent area 390 over the common power line 320. Further, the display area 370 is disposed between a thin film transistor area 360 where a thin film transistor is formed and the transparent area 390, and a gate line 350 is formed adjacent to the thin film transistor area 360.

In the display area 370, a first opaque display unit 371 emits light of a red-based color, a second opaque display unit 372 emits light of a green-based color, and a third opaque display unit 373 emits light of a blue-based color. In this case, the display area 370 emits light through bottom light emission. For this, the cathode of the organic light emitting diode formed in the display area 370 may be formed with a material (e.g., Al or Ag) that s opaque and reflects light.

The transparent area 390 is formed to be transflective dual emission and emits light. That is, in the transparent area 390, a first transparent display unit 391 emits light of a red-based color, a second transparent display unit 392 emits light of a green-based color, and a third transparent display unit 393 emits light of a blue-based color. In this case, the first, second, and third transparent display areas 391, 392, and 393 are dual emission. For this, a cathode of an organic light emitting diode formed in the transparent area 390 may be formed of a material such as Mg, Ag, or Yb. That is, in the third exemplary embodiment, the cathode disposed in the transparent area 390 may be formed with a material that can transmit light emitted from the organic emission layer and display a color when the cathode is transparent or even though it is not completely transparent.

In the third exemplary embodiment, an anode of the transparent area 390 and an anode of the opaque area 370 in each pixel may be connected with each other or separated from each other and then connected with the corresponding driving circuit. When the anodes of both areas are connected with each other, they may be formed as a single pattern, and if they are separated from each other, maintenance for a pixel failure can be easily performed.

According to the third exemplary embodiment, in each pixel of the OLED display 103, the display area 370 formed as a bottom emission type and the transparent area 390 formed as a dual emission type are separated from each other by the common power line 320 so that the cathode of the organic light emitting diode disposed in the display area 370 does not interfere with the display area 370 because of the common power line 320. Further, in the OLED display according to the third exemplary embodiment, the displays 391, 392, and 393 are formed in the transparent area 390 so that the transparent area 390 may emit light through dual sides as necessary.

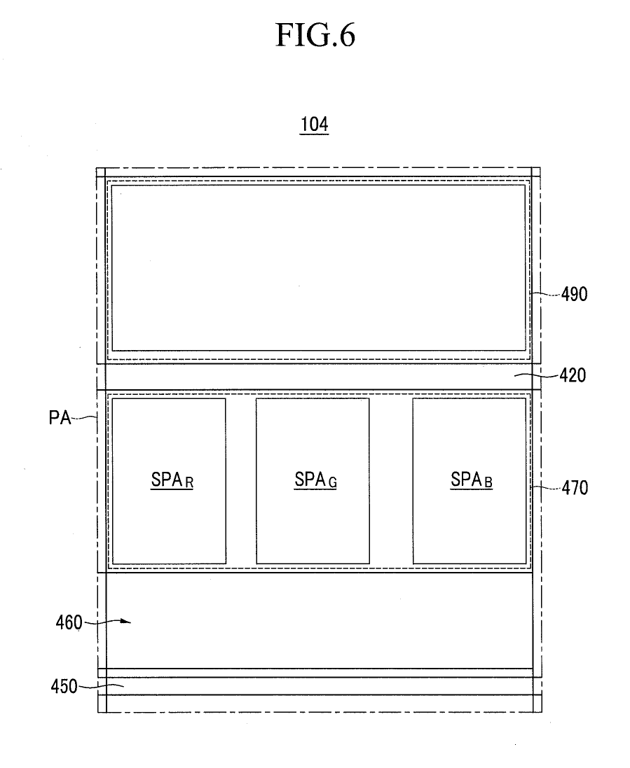

FIG. 6 is a layout view of an OLED display 104 according to a fourth exemplary embodiment. The OLED display 104 according to the fourth exemplary embodiment is formed with a structure that is the similar to the above-described exemplary embodiments, but the number of sub-pixels of a transparent area 490 is less than the number of sub-pixels of a display area 470. For example, as shown in FIG. 6, the number of sub-pixels SPA_{R}, SPA_{G}, and SPA_{B} disposed in the display area 470 is three corresponding to R, G, and B, but the transparent 490 is patterned to be one area corresponding to the three sub-pixels SPA_{R}, SPA_{G}, and SPA_{B}. As described, the pattern of the display unit of the transparent area 490 is advantageous to minimize distortion of an image transmitted through the transparent area.

As shown in FIG. 6, in the OLED display 104 according to the fourth exemplary embodiment, a conductive line separating the transparent area 490 and the display area 470 is used a common power line 420 in the pixel area PA and a gate line 450 is formed neighboring a thin film transistor area 460, but arrangement of the common power line 420 and the gate line 450 may be reversed.

While this disclosure has been described in connection with what is presently considered to be practical exemplary embodiments, it is to be understood that the invention is not limited to the disclosed embodiments, but, on the contrary, is intended to cover various modifications and equivalent arrangements.

What is claimed is:

1. An organic light emitting diode (OLED) display comprising:
a substrate main body having a plurality of pixel areas formed thereon, wherein each pixel area comprises:
an opaque area, the opaque area including a display area that emits light, and
a transparent area,
wherein the display area and the transparent area are separated by a conductive line disposed therebetween.

2. The OLED display of claim 1, wherein the conductive line is a common power line.

3. The OLED display of claim 1, wherein the conductive line is a gate line.

4. The OLED display of claim 1, wherein an organic light emitting diode including an anode, a cathode, and an organic emission layer formed between the anode and the cathode is formed in the display area, and the conductive line is disposed between the transparent area and the cathode.

5. The OLED display of claim 1, wherein the transparent area is patterned with a number of areas that is the same as the number of sub-pixel areas in the opaque area.

6. The OLED display of claim 1, wherein the transparent area is patterned with a number of areas that is less than the number of sub-pixels in the opaque area.

7. The OLED display of claim 6, wherein the number of transparent areas is 1.

8. An organic light emitting diode (OLED) display comprising:
a substrate main body having a plurality of pixel areas formed thereon, wherein each pixel area comprises:
an opaque area including a display area configured to emit light, and
a transparent area,
wherein the display area and the transparent area are separated by a conductive line disposed between the display area and the transparent area; and
a transparent display unit configured to emit light formed in the transparent area.

9. The OLED display of claim 8, wherein the conductive line is a common power line.

10. The OLED display of claim 8, wherein the conductive line is a gate line.

11. The OLED display of claim 8, wherein an organic light emitting diode including an anode, a cathode, and an organic emission layer formed between the anode and the cathode is formed in the display area, and the conductive line is disposed between the transparent area and the cathode.

12. The OLED display of claim 8, wherein the transparent display unit includes a transparent cathode.

13. The OLED display of claim 12, wherein the cathode includes Mg, Ag, or Yb.

14. The OLED display of claim 8, wherein an opaque display unit formed as a bottom emission type is formed in the opaque area.

15. The OLED display of claim 14, wherein an anode of the transparent display unit and an anode of the opaque display unit of the opaque area are connected with each other.

16. The OLED display of claim 14, wherein an anode of the transparent display unit and an anode of the opaque display unit of the opaque area are separated from each other.
